(19) United States
(12) Patent Application Publication
(10) Pub. No.: US 2025/0201580 A1
(43) Pub. Date: Jun. 19, 2025

(54) METHOD OF MANUFACTURING SEMICONDUCTOR DEVICE

(71) Applicant: FUJI ELECTRIC CO., LTD., Kawasaki-shi (JP)

(72) Inventor: Tatsuya HASHIMOTO, Azumino-city (JP)

(73) Assignee: FUJI ELECTRIC CO., LTD., Kawasaki-shi (JP)

(21) Appl. No.: 18/934,219

(22) Filed: Oct. 31, 2024

(30) Foreign Application Priority Data
Dec. 13, 2023 (JP) 2023-210438

(51) Int. Cl. H01L 21/324; H01L 21/304; H01L 21/78

(52) U.S. Cl. CPC H01L 21/324; H01L 21/304; H01L 21/78

(57) ABSTRACT

A method of manufacturing a semiconductor device, including: providing a semiconductor wafer having a first main surface and a second main surface; forming a back device element structure in the semiconductor wafer, at the second main surface; subsequently, heating the semiconductor wafer in a furnace; subsequently, protecting the second main surface of the semiconductor wafer using a back surface protective film; subsequently, performing a process to at least the first main surface of the semiconductor wafer while the second main surface of the semiconductor wafer is protected by the back surface protective film, including applying a heat treatment (annealing process) of 200 degrees C. or higher; and subsequently, removing the back surface protective film. The back surface protective film is formed using a non-photosensitive resin material, and is formed to be heat resistant to a temperature of 200 degrees C. or higher.

### CROSS REFERENCE TO RELATED APPLICATIONS

This application is based upon and claims the benefit of priority of the prior Japanese Patent Application No. 2023-210438, filed on Dec. 13, 2023, the entire contents of which are incorporated herein by reference.

### BACKGROUND OF THE INVENTION

### 1. Field of the Invention

Embodiments of the disclosure relate to a method of manufacturing a semiconductor device.

### 2. Description of the Related Art

Japanese Laid-Open Patent Publication No. 2017-104794 describes a technique that suppresses adhesion of a polyimide at a back surface of a wafer by using a rod-shaped member provided in a periphery of the wafer to thereby capture the polyimide, which is in a mist-form and scattered in the periphery of the wafer by centrifugal force when a polyimide-based resin membrane is formed at a front surface of the wafer using a spin coater. Japanese Laid-Open Patent Publication No. 2017-228732 describes a technique of preventing adhesion of foreign matter and damage of a metal layer of a back surface of a wafer by covering the metal layer of the back surface of the wafer with a protective film when the wafer is cut.

### SUMMARY OF THE INVENTION

According to an embodiment of the present disclosure, a method of manufacturing a semiconductor device having a semiconductor substrate having a front surface and a back surface, a front device element structure formed at the front surface of the semiconductor substrate, and a back device element structure formed at the back surface of the semiconductor substrate, the method comprising: providing a semiconductor wafer having a first main surface and a second main surface; as a back surface process, forming the back device element structure in the semiconductor wafer at the second main surface; as a thermal process, heating the semiconductor wafer in a furnace after performing the back surface process; as a back surface protection process, protecting the second main surface of the semiconductor wafer using a back surface protective film after performing the thermal process; as a front surface process, performing a process to at least the first main surface of the semiconductor wafer while the second main surface of the semiconductor wafer is being protected by the back surface protective film, said process including a heat treatment of 200 degrees C. or higher; and as a removal process, removing the back surface protective film after performing the front surface process. The back surface protection process further includes forming the back surface protective film using a non-photosensitive resin material, the back surface protective film being heat resistant to a temperature of 200 degrees C. or higher.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a flowchart showing an outline of a method of manufacturing a semiconductor device according to a first embodiment.

FIG. 2 is a cross-sectional view depicting schematically a state of the semiconductor device according to the first embodiment during manufacture.

FIG. 3 is a cross-sectional view depicting schematically a state of the semiconductor device according to the first embodiment during manufacture.

FIG. 4 is a cross-sectional view depicting schematically a state of the semiconductor device according to the first embodiment during manufacture.

FIG. 5 is a cross-sectional view depicting schematically a state of the semiconductor device according to the first embodiment during manufacture.

FIG. 6 is a cross-sectional view depicting schematically a state of the semiconductor device according to the first embodiment during manufacture.

FIG. 7 is a cross-sectional view depicting schematically a state of the semiconductor device according to the first embodiment during manufacture.

FIG. 8 is a cross-sectional view depicting schematically a state of the semiconductor device according to the first embodiment during manufacture.

FIG. 9 is a cross-sectional view depicting schematically a state of the semiconductor device according to the first embodiment during manufacture.

FIG. 10 is a cross-sectional view depicting schematically a state of the semiconductor device according to the first embodiment during manufacture.

FIG. 11 is a cross-sectional view depicting schematically a state of the semiconductor device according to the first embodiment during manufacture.

FIG. 12 is a cross-sectional view depicting schematically a state of the semiconductor device according to the first embodiment during manufacture.

FIG. 13 is a cross-sectional view depicting schematically a state of the semiconductor device according to the first embodiment during manufacture.

FIG. 14 is a cross-sectional view of an example of the structure of the semiconductor device fabricated by the method of manufacturing the semiconductor device according to the first embodiment.

FIG. 15 is a flowchart showing an outline of a method of manufacturing a semiconductor device according to a second embodiment.

FIG. 16 is a characteristics diagram schematically depicting a relationship between a scratch occurrence rate of a back surface of the semiconductor wafer and thickness of the back surface protective film.

FIG. 17 is a characteristics diagram schematically depicting a defective chip occurrence rate per semiconductor wafer.

FIG. 18 is a flowchart showing an outline of a method of manufacturing a semiconductor device of a first reference example.

FIG. 19 is a flowchart showing an outline of another example of a method of manufacturing a semiconductor device of a second reference example.

FIG. 20 is a cross-sectional view schematically depicting a state of the semiconductor device of the second reference example during manufacture.

FIG. 21 is a cross-sectional view schematically depicting a state of the semiconductor device of the second reference example during manufacture.

FIG. 22 is a cross-sectional view schematically depicting a state of the semiconductor device of the second reference example during manufacture.

FIG. 23 is a cross-sectional view schematically depicting a state of the semiconductor device of the second reference example during manufacture.

FIG. 24 is a cross-sectional view schematically depicting a state of the semiconductor device of the second reference example during manufacture.

### DETAILED DESCRIPTION OF THE INVENTION

First, problems associated with the conventional techniques are discussed. In Japanese Laid-Open Patent Publication No. 2017-104794, when the polyimide is applied to the front surface of the wafer, the back surface of the wafer is exposed and thus, adhesion of the polyimide at the back surface of the wafer cannot be completely prevented. Further, the back surface of the wafer is in direct contact with a support stage of the spin coater and thus, a defect such as contamination or a scratch may occur at the back surface of the wafer. Foreign matter adhered to the back surface of the wafer causes thermal destruction during device operation and defects such as contamination and scratches occurring at the back surface of the wafer cause leakage (current leakage) defects. Thus, defects and foreign matter at the back surface of the wafer tend to adversely affect product yield and cause product yield to decrease.

In light of these problems, an overview of the present disclosure is described. (1) A method of manufacturing a semiconductor device according to one embodiment of the present disclosure is a method of manufacturing a semiconductor device having a predetermined front device element structure and a predetermined back device element structure at first and second main surfaces, respectively, and is as follows. A back surface process of forming the back device element structure in the semiconductor wafer, at the second main surface is performed. After the back surface process, a thermal process of heating the semiconductor wafer in a furnace is performed. After the thermal process, a back surface protection process of protecting the second main surface of the semiconductor wafer by a back surface protective film is performed. A front surface process of performing a process to at least the first main surface of the semiconductor wafer while the second main surface of the semiconductor wafer is protected by the back surface protective film is performed, said process including a heat treatment (annealing process) of 200 degrees C. or higher. After the front surface process, a removal process of removing the back surface protective film is performed. The back surface protection process includes forming the back surface protective film using a non-photosensitive resin material and the back surface protective film has a heat-resistant temperature of 200 degrees C. or higher.

According to the disclosure above, during the front surface process, the second main surface of the semiconductor wafer is protected by the back surface protective film, whereby defects (scratches, contamination) that are factors contributing to leakage defects may be suppressed at the second main surface of the semiconductor wafer. Further, adhesion of foreign matter to the second main surface of the semiconductor wafer which is a factor contributing to thermal destruction during device operation may be suppressed. Thus, product (semiconductor device) yield may be enhanced.

(2) Further, in the method of manufacturing the semiconductor device according to the present disclosure, in (1) above, in the back surface protection process, the back surface protective film may be formed using a non-photosensitive resin material soluble in an organic solvent.

According to the disclosure above, the material of the back surface protective film applied to the second main surface of the semiconductor wafer contains an organic solvent, which may be vaporized by a heat treatment (annealing process) of a relatively low temperature, whereby the back surface protective film may be formed.

(3) Further, in the method of manufacturing the semiconductor device according to the present disclosure, in (1) or (2), in the back surface protection process, the back surface protective film may be formed using a closed-ring polyimide-based material.

According to the disclosure above, a back surface protective film that has a higher heat resistance temperature than that of a resist and that further has mechanical properties (elongation) similar to those of the polyimide material used in the passivation film may be formed.

(4) Further, in the method of manufacturing the semiconductor device according to the present disclosure, in any one of (1) to (3) above, in back surface protection process, a thickness of the back surface protective film may be 1 μm or more.

According to the disclosure above, the effect of suppressing the occurrence of defects at the second main surface of the semiconductor wafer during the front surface process is increased.

(5) Further, in the method of manufacturing the semiconductor device according to the present disclosure, in any one of (1) to (4) above, the front surface process may include applying a polyimide to the front surface of the semiconductor wafer by a spin-coat method thereby forming the passivation film and the heat treatment is for curing the passivation film.

According to the disclosure above, the thermal process may be performed at a temperature exceeding the heat-resistant temperature of the passivation film. Further, adhesion of the material of the passivation film to the second main surface of the semiconductor wafer during formation of the passivation film may be prevented.

(6) Further, the method of manufacturing the semiconductor device according to the present disclosure, in any one of (1) to (5) above, further includes forming the front device element structure in the semiconductor wafer, at the first main surface before performing the back surface process. The front surface process may include forming, at the front surface of the semiconductor wafer, a front electrode electrically connected to the front device element structure and the heat treatment is for sintering the front electrode.

According to the disclosure above, the thermal process may be performed at a temperature that exceeds the heat-resistant temperature of the front electrode.

(7) Further, in the method of manufacturing the semiconductor device according to the present disclosure, in any one of (1) to (6) above, in the back surface process, a diffused region of a predetermined conductivity type and configuring the back device element structure may be formed by ion-implanting a dopant from the second main surface of the semiconductor wafer and in the thermal process, the dopant may be activated.

According to the disclosure above, dopant activation of the back device element structures may be performed by a temperature that exceeds the heat-resistant temperatures of the passivation film and the front electrode.

(8) Further, in the method of manufacturing the semiconductor device according to the present disclosure, in any one of (1) to (7) above, in the removal process, the back surface protective film may be dissolved in an organic solvent and thereby removed.

According to the disclosure above, the back surface protective film may be removed without applying stress to the semiconductor wafer and without leaving residue such as adhesive on the second main surface of the semiconductor wafer.

(9) Further, in the method of manufacturing the semiconductor device according to the present disclosure, in any one of (1) to (8) above, a back electrode electrically connected to the back device element structure may be formed at the second main surface of the semiconductor wafer after the removal process.

According to the disclosure above, even when the semiconductor wafer warps due to the formation of the back electrode, of all the manufacturing processes, the number of processes to be performed after the formation of the back electrode may be reduced and thus, cracking of the semiconductor wafer during the manufacturing processes may be suppressed. Further, leakage defects caused by metal atoms in the back electrode diffusing into the semiconductor wafer may be suppressed.

Findings underlying the present disclosure are discussed. In a vertical semiconductor device in which a device element structure and a surface electrode are formed on both main surfaces of a semiconductor substrate such as, for example, an insulated gate bipolar transistor (IGBT) or a reverse conducting IGBT (RC-IGBT) in which an IGBT and a diode are implemented on a single semiconductor substrate, in general, processes for a front side of a semiconductor wafer are performed with the semiconductor wafer having a thick thickness (for example, 600 μm or more) and thereafter, the semiconductor wafer is ground from a back surface (second main surface) thereof, thereby reducing the thickness and subsequently, processes for a back side of the semiconductor wafer are performed. As a method of manufacturing a semiconductor device of a first reference example, a method of manufacturing a general vertical semiconductor device is described.

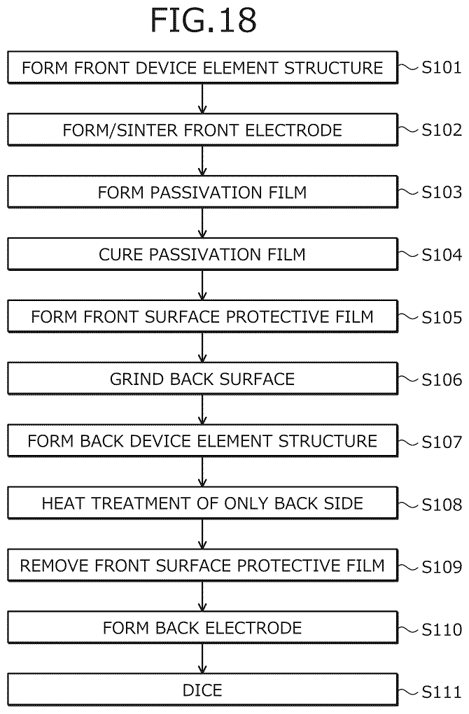

FIG. 18 is a flowchart showing an outline of the method of manufacturing the semiconductor device of the first reference example. In particular, a semiconductor wafer containing silicon (Si) is prepared and device element structures (hereinafter, front device element structures) of a front side of the semiconductor wafer are formed (step S101). Next, surface electrodes (hereinafter, front electrodes) of the front side of the semiconductor wafer are deposited (formed) and sintered (step S102). Next, a passivation film is formed and cured (hardened) at a front surface (first main surface) of the semiconductor wafer (steps S103, S104) and thereafter, the front surface of the semiconductor wafer is covered and protected by a protective film (hereinafter, front surface protective film) (step S105). Next, the semiconductor wafer is ground from the back surface thereof and made thinner (step S106).

Next, device element structures (hereinafter, back device element structures) of a back side of the semiconductor wafer are formed by, for example, ion implantation, etc. (step S107). Next, an annealing process for activating dopants ion-implanted to form the back device element structures (hereinafter, dopant activation of the back device element structures) is performed (step S108). In the annealing process at step S108, only the back side of the semiconductor wafer is heated by laser irradiation, etc. Subsequently, the front surface protective film is removed (step S109). Next, a surface electrode (hereinafter, back electrode) at the back surface of the semiconductor wafer is formed (step S110). Thereafter, the semiconductor wafer is diced (cut) into individual chips (step S111), whereby the semiconductor device (semiconductor chip) is completed.

Depending on the product (semiconductor device), the annealing process for dopant activation of the back device element structures of the semiconductor wafer has to be performed using a furnace. In this case, the temperature of the annealing process by the furnace is 450 degrees C. or higher and, in some instances, may be in range of about 500 degrees C. to 800 degrees C. In the annealing process by the furnace, the entire semiconductor wafer is heated and thus, among the front electrode and structure components of the front device element structure, structure components that cannot withstand the temperature of the annealing process by the furnace have to be formed after the annealing process by the furnace. For example, a polyimide, which is a material of the passivation film, has a heat-resistant temperature in a range of about 350 degrees C. to 400 degrees C. and may be lower in some instances. Aluminum (Al), which is a material of the front electrode. has a heat-resistant temperature about 500 degrees C.

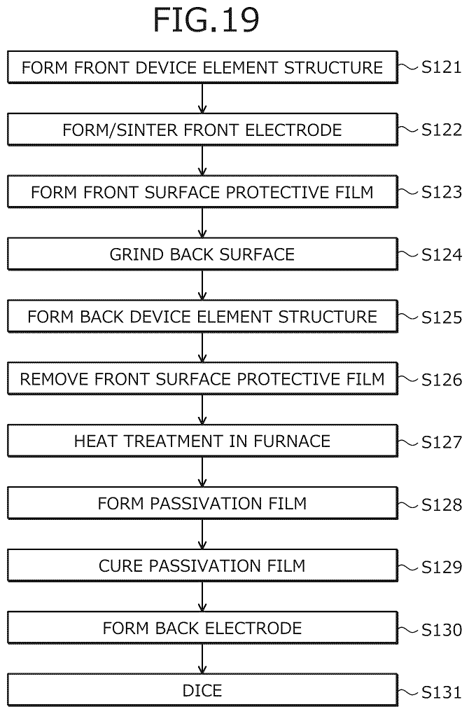

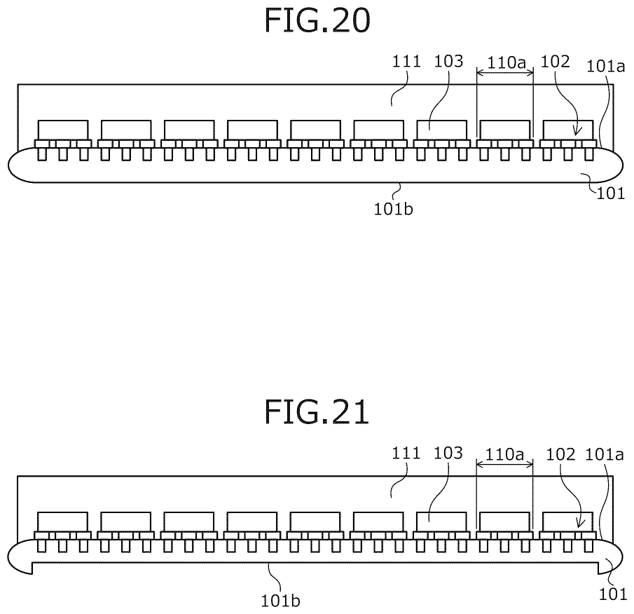

As a method of manufacturing a semiconductor device of a second reference example, an instance in which an annealing process of a temperature of about 450 degrees C. is performed by a furnace is described. FIG. 19 is a flowchart showing an outline of another example of a method of manufacturing a semiconductor device of a second reference example. FIGS. 20, 21, 22, 23, and 24 are cross-sectional views schematically depicting states of the semiconductor device of the second reference example during manufacture. The method of manufacturing the semiconductor device of the second reference example differs from the method of manufacturing the semiconductor device of the first reference example (refer to FIG. 18) in that the annealing process for dopant activation of back device element structures 104 is performed using a furnace and timings of the formation and curing of a passivation film 105 differ from those in the method of manufacturing the semiconductor device of the first reference example. In particular, first, a semiconductor wafer 101 is prepared and in the semiconductor wafer 101, at a front surface 101a thereof, front device element structures 102 are formed (step S121).

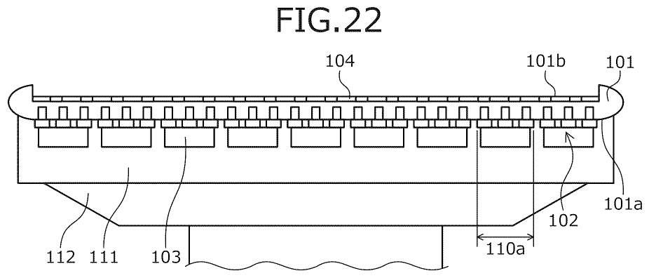

Next, at the front surface 101a of the semiconductor wafer 101, front electrodes 103 are formed and sintered (step S122). Next, the front surface 101a of the semiconductor wafer 101 is covered and protected by a front surface protective film 111 (step S123). The state up to here is depicted in FIG. 20. Next, the semiconductor wafer 101 is ground from the back surface thereof and made thinner (step S124, FIG. 21). Next, the semiconductor wafer 101 is placed on a stage 112 of semiconductor manufacturing equipment with the front surface 101a facing downward (facing the stage 112) via the front surface protective film 111 and the back device element structures 104 of the semiconductor wafer 101 are formed by ion implantation, etc. (step S125, FIG. 22). Subsequently, the front surface protective film 111 is removed (step S126).

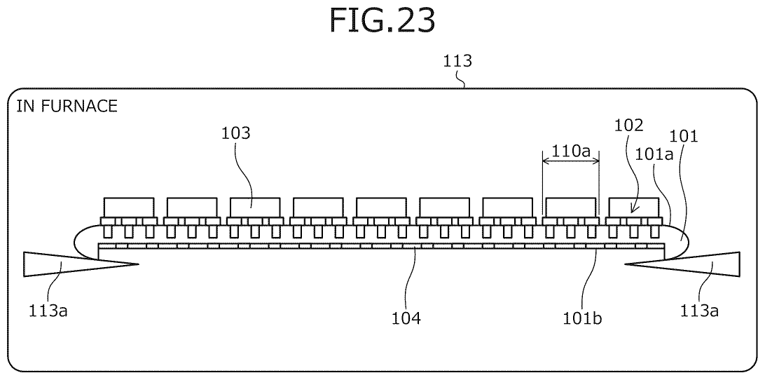

Next, the semiconductor wafer 101 is placed in a furnace (annealing furnace) 113 and the annealing process for dopant activation of the back device element structures 104 is performed at a temperature of about 450 degrees C. (step S127, FIG. 23). The semiconductor wafer 101, for example, is supported from below by multiple wafer supports 113a and kept at a predetermined position in the furnace 113. In an instance in which an outer periphery of the semiconductor wafer 101 has a rib-like shape that remains thicker than a center portion of the semiconductor wafer 101, the process at step S127 may be performed with the semiconductor wafer 101 being placed in the furnace 113 with a back surface 101b of the semiconductor wafer 101 facing downward and a rib portion (outer peripheral portion that protrudes more than the center portion) at the back surface 101b being supported by the wafer supports 113a.

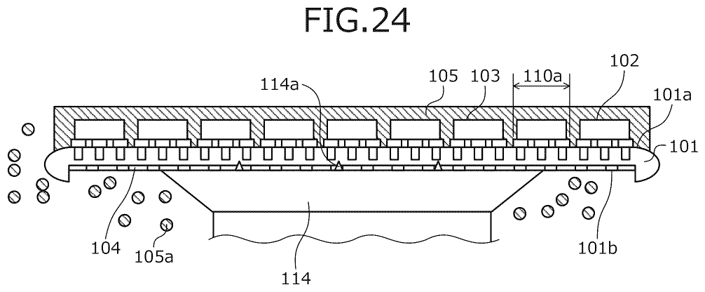

Next, the semiconductor wafer 101 is placed on a stage 114 of a spin coater with the back surface 101b facing downward (facing the stage 114) and a polyimide 105a (portion with oblique line hatching) is applied to the front surface 101a of the semiconductor wafer 101, thereby forming the passivation film 105 (step S128, FIG. 24). In the process at step S128, the passivation film 105 may be patterned by photolithography and etching. In the passivation film 105, openings that expose scribe regions and electrode pads may be formed by patterning. Next, the passivation film 105 is cured by an annealing process (step S129). Thereafter, a back electrode (not depicted) is formed (step S130) and the semiconductor wafer 101 is diced into individual chips (step S131), thereby completing the semiconductor devices.

Chip regions 110a are portions of the semiconductor wafer 101 into which the semiconductor wafer 101 is diced at step S131, each of the chip regions 110a constituting a semiconductor chip (semiconductor device). In FIGS. 20 to 24, arrangement, shapes and sizes of the structure components (the front device element structures 102, the front electrodes 103, the back device element structures 104, the passivation film 105) in the semiconductor wafer 101 and on the main surfaces thereof (the front surface 101a and the back surface 101b) and in FIG. 24, shapes and sizes of foreign matter 114a (depicted as triangular shapes) on the stage 114 and the polyimide 105a (depicted as circular shapes with oblique hatching) in a mist state and floating in a periphery of the stage 114 are simplified for the sake of description of the method of manufacturing the semiconductor device of the second reference example and differ from actual shapes and sizes.

As described, when predetermined processes are performed at the front surface 101a of the semiconductor wafer 101 (treated surface) with the back surface 101b (non-treated surface) of the semiconductor wafer 101 being exposed, the back surface 101b of the semiconductor wafer 101 is in contact with the stage 114 of the semiconductor manufacturing equipment (refer to FIG. 24). Therefore, defects such as scratches and contamination easily occur at the back surface 101b of the semiconductor wafer 101 due to the foreign matter 114a (depicted as triangular shapes) on the stage 114. In particular, when a polyimide is applied to the front surface 101a of the semiconductor wafer 101 by a spin-coat method, the polyimide 105a (depicted as circular shapes), which is in a mist state, may adhere to the back surface 101b of the semiconductor wafer 101. The polyimide 105a that has adhered to the back surface 101b of the semiconductor wafer 101 cannot be easily removed.

Furthermore, to expose a polyimide film applied to the front surface 101a of the semiconductor wafer 101 and transfer a predetermined pattern of the passivation film 105, the semiconductor wafer 101 has to be transported to exposure equipment (not depicted) and placed on a stage of the exposure equipment with the back surface 101b facing downward. Therefore, adhesion of foreign matter and the occurrence of defects at the back surface 101b of the semiconductor wafer 101 is unavoidable. Foreign matter adhered to the back surface of a semiconductor chip diced from the semiconductor wafer 101 is one factor contributing to thermal destruction during device operation and defects such as contamination and scratches occurring at the back surface of the semiconductor chip are factors contributing to leakage (current leakage) defects. Thus, foreign matter and defects at the back surface 101b of the semiconductor wafer 101 tend to adversely affect product yield and cause decreased product yield.

In the present embodiment, as one problem to be solved, a method of manufacturing a vertical semiconductor device having device element structures (front device element structures and back device element structures), respectively, at main surfaces of a semiconductor substrate suppresses adhesion of foreign matter and the occurrence of defects (scratches, contamination) at the back surface of the semiconductor wafer to thereby enhance product yield.

Embodiments of a method of manufacturing a semiconductor device according to the present disclosure are described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical are given the same reference numerals and are not repeatedly described.

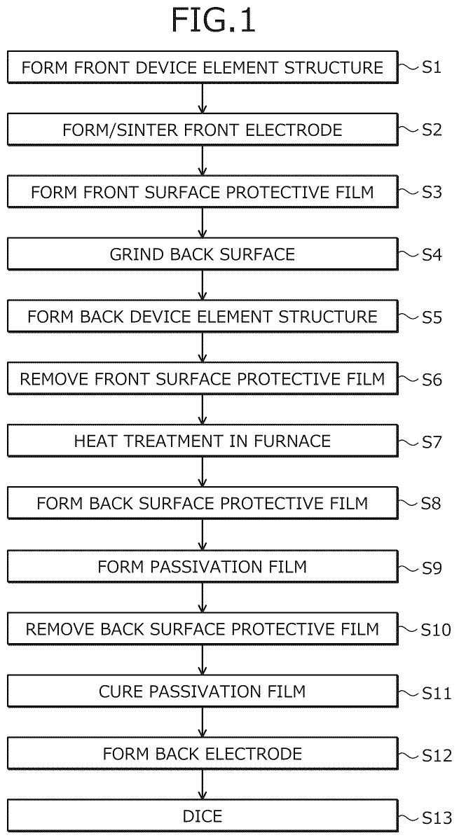

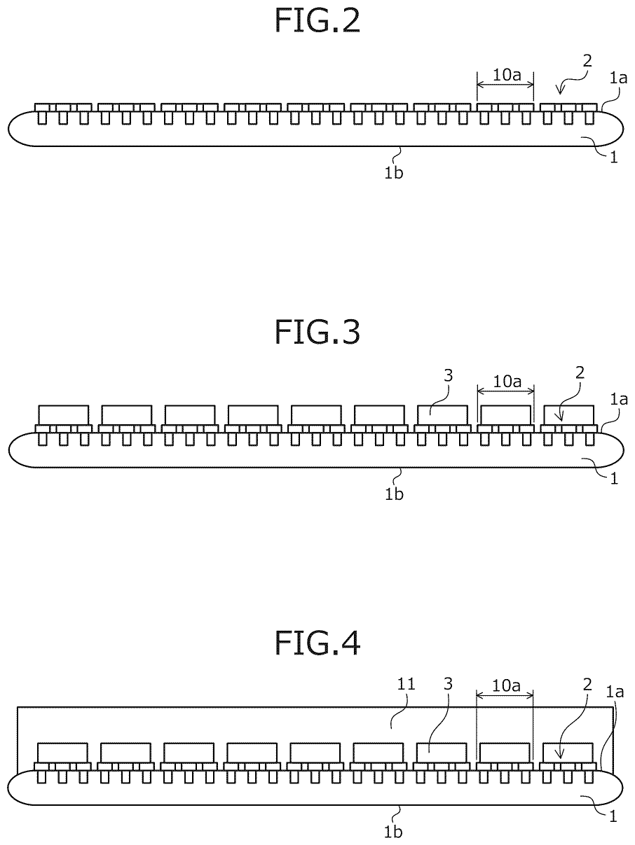

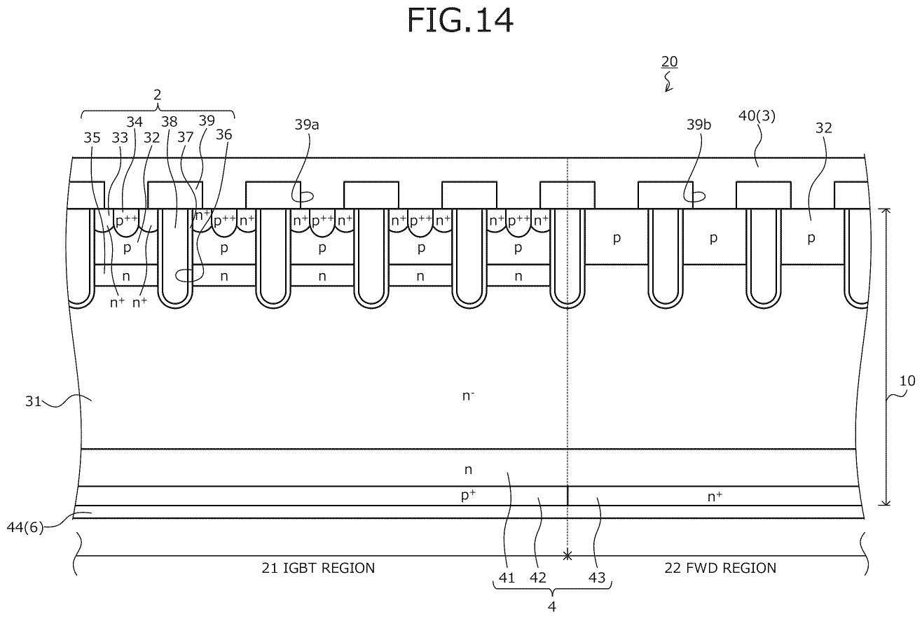

A method of manufacturing a semiconductor device according to a first embodiment solving the problems above is described taking, as an example, an instance in which an IGBT is fabricated (manufactured). FIG. 1 is a flowchart showing an outline of the method of manufacturing the semiconductor device according to the first embodiment. FIGS. 2, 3, 4, 5, 6, 7, 8, 9, 10, 11, 12, and 13 are cross-sectional views depicting schematically states of a semiconductor device according to the first embodiment during manufacture. In FIGS. 2 to 13 and in later-described FIG. 14, parts are depicted in a simplified manner. First, as depicted in FIG. 2, a semiconductor wafer 1 is prepared and in the semiconductor wafer 1, at a front surface 1a thereof, device element structures (front device element structures) 2 are formed in each of multiple chip regions 10a of the semiconductor wafer 1 (step S1). Next, as depicted in FIG. 3, at the front surface 1a of the semiconductor wafer 1, a surface electrode (front electrode) 3 is deposited (formed) and sintered in each of the chip regions 10a (step S2).

The semiconductor wafer 1 has a diameter and a thickness of, for example, 8 inches and about 725 μm, respectively. A semiconductor material of the semiconductor wafer 1 may be silicon (Si) or silicon carbide (SiC). The front device element structures 2 are a MOS gate (metal oxide semiconductor field effect transistor: insulated gate having a three-layer metal-oxide-semiconductor structure) structure and an interlayer insulating film. The front device element structures 2 reach, for example, depths less than 10 μm from the front surface 1a of the semiconductor wafer 1. The chip regions 10a are regions cut from the semiconductor wafer 1 into individual chips (semiconductor chips 10, refer to FIG. 13).

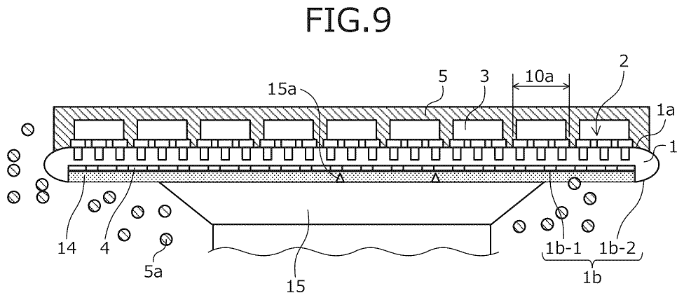

Front electrodes 3 are emitter electrodes. The front electrodes 3 are constituted by, for example, an aluminum (Al) layer or an Al alloy layer. In FIGS. 2 to 13, arrangement, shapes, and sizes of structure components (the front device element structures 2, the front electrodes 3, later-described back device element structures 4, a later-described passivation film 5, and a later-described back electrode 6) in the semiconductor wafer 1 or on the main surfaces thereof (the front surface 1a and a back surface 1b); and in FIG. 9, shapes and sizes of foreign matter 15a (depicted as triangular shapes) on a stage 15 and a polyimide 5a (depicted as circular shapes with oblique hatching) in a mist state and floating in a periphery of the stage 15 are simplified for the sake of description of the method of manufacturing the semiconductor device according to the first embodiment and differ from actual shapes and sizes.

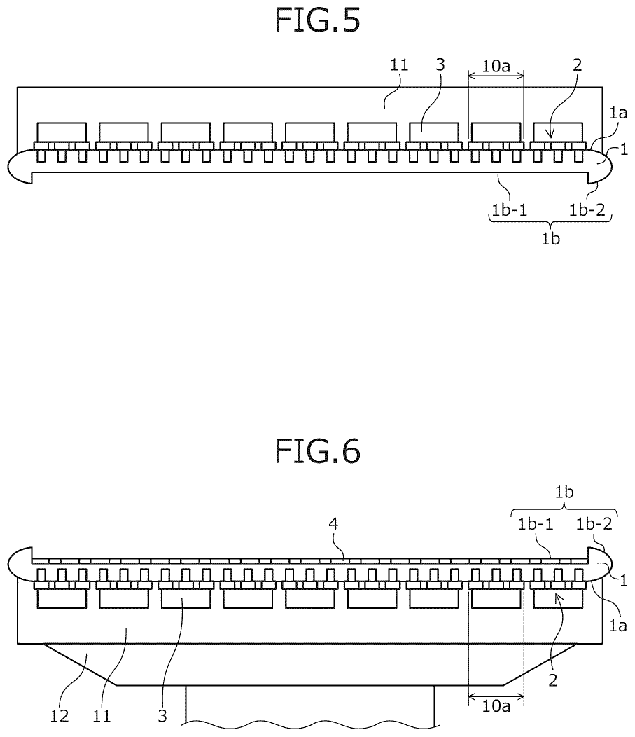

Next, as depicted in FIG. 4, the front surface 1a of the semiconductor wafer 1 is covered and protected by a protective film (front surface protective film) 11 (step S3). The front surface protective film 11, for example, is a resist film. Next, as depicted in FIG. 5, the semiconductor wafer 1 is ground from the back surface 1b (back surface grinding) to reduce the thickness thereof to a product thickness (for example, a range of about 50 μm to 300 μm) used for a semiconductor device (each of the semiconductor chips 10) (step S4). In the process at step S4, the entire surface of the semiconductor wafer 1 may be ground uniformly to the product thickness so as to form a plate-like shape (not depicted), or the thickness of the semiconductor wafer 1 may be reduced by grinding only a center portion 1b-1 of the semiconductor wafer 1 to the product thickness and leaving an outer peripheral portion 1b-2 thereof along the outer periphery to have a predetermined width and a thickness greater than the thickness at the center portion 1b-1, thereby forming a rib-like shape (FIG. 5).

Next, as depicted in FIG. 6, the device element structures (back device element structures) 4 of the back surface 1b of the semiconductor wafer 1 are formed (step S5: back surface process). The back device element structures 4 are a p⁺-type collector region and an n-type field stop (FS) layer. In particular, in the process at step S5, the semiconductor wafer 1 is placed on a stage 12 of ion implantation equipment with the front surface 1a facing downward (facing the stage 12) via the front surface protective film 11 and dopants are ion-implanted from the back surface 1b of the semiconductor wafer 1, thereby forming diffused regions of predetermined conductivity types configuring the back device element structures 4. The back device element structures 4 may reach depths that are at maximum, for example, about 30 μm from the back surface 1b of the semiconductor wafer 1. Subsequently, the front surface protective film 11 is removed (step S6).

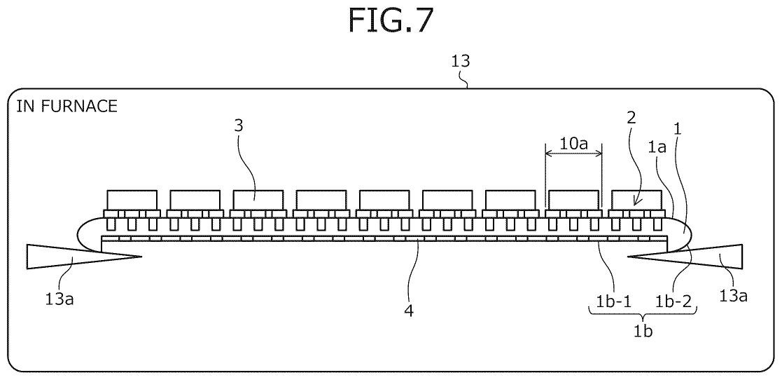

Next, as depicted in FIG. 7, the semiconductor wafer 1 is placed in a furnace (annealing furnace) 13 and maintained so as to be apart from inner walls of the furnace 13 while an annealing process (heat treatment) for recovery of crystal defects is performed at a high temperature of, for example, 450 degrees C. or higher, the crystal defects being generated by activating the dopants ion-implanted by the process at step S5 (dopant activation of the back device element structures 4), the ion implantation process, and thermal diffusion of the dopants (step S7: thermal process). At this time, the semiconductor wafer 1, for example, suffices to be placed in the furnace 13 with the back surface 1b facing downward and maintained at a predetermined position while being supported from below by multiple wafer supports 13a (for example, 4) in the furnace 13. As a result, the wafer supports 13a are not in contact with the front device element structures 2 or the front electrodes 3 of the front surface 1a of the semiconductor wafer 1.

Further, preferably, the wafer supports 13a may each be in contact with a different area of a rib portion (the outer peripheral portion 1b-2 that protrudes more than the center portion 1b-1) of the back surface 1b of the semiconductor wafer 1 and support the semiconductor wafer 1. As a result, the back device element structures 4 of the back surface 1b of the semiconductor wafer 1 are also free of contact with the wafer supports 13a. Further, the annealing process by the furnace 13 at step S7 heats the entire semiconductor wafer 1 and thus, structure components that cannot withstand the temperature of the annealing process by the furnace 13 are formed after the process at step S7. For example, the heat-resistant temperature of polyimide, which is a material of the passivation film 5 (refer to later-described FIG. 9), for example, is in a range of about 350 degrees C. to 400 degrees C. and may be lower in some instances. The heat-resistant temperature of the resist that is a material of the front surface protective film 11 removed before the process at step S7 is, for example, in a range of about 150 degrees C. to 200 degrees C.

For example, in an instance in which dopant activation of the back device element structures is performed by laser irradiation like in the method of manufacturing the semiconductor device of the first reference example (refer to FIG. 18), only a shallow region to a depth of about 1 μm (maximum depth of about 2 μm) from the back surface of the semiconductor wafer is heated. Thus, the back device element structure may only be formed in a shallow region of a depth not more than about 2 μm from the back surface of the semiconductor wafer or a region having insufficient dopant activation is formed. On the other hand, in the first embodiment, the entire semiconductor wafer 1 is heated by the annealing process by the furnace 13 and thus, the back device element structures 4 may be formed disposed in regions of a predetermined conductivity type, the regions having a depth up to, for example, a maximum of about 30 μm from the back surface 1b of the semiconductor wafer 1.

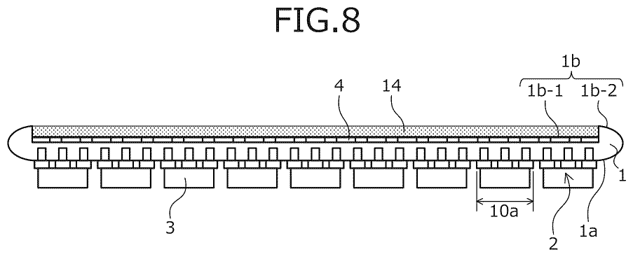

Next, as depicted in FIG. 8, the semiconductor wafer 1 is removed from the furnace 13 and thereafter, by a spin-coat method using a spin coater, the back surface 1b of the semiconductor wafer 1 is covered and protected by a protective film (hereinafter, back surface protective film) 14 (step S8: back surface protection process). In particular, the outer peripheral portion 1b-2 of the semiconductor wafer 1 is clamped (pinched and held by a jig) with the back surface 1b of the semiconductor wafer 1 (treated surface) facing upward. The semiconductor wafer 1 is maintained at a predetermined height position without being in contact with the stage, etc. Further, while the semiconductor wafer 1 is rotated around a shaft that is orthogonal to the back surface 1b of the semiconductor wafer 1 and penetrates through substantially a center of the semiconductor wafer 1, a material of the back surface protective film 14 is applied from above and spread on the back surface 1b of the semiconductor wafer 1, thereby forming the back surface protective film 14 (hatched portion).

As a material for the back surface protective film 14, a non-photosensitive resin material soluble in an organic solvent is used. In particular, the material for the back surface protective film 14 may be, for example, a closed-ring polyimide-based material obtained by dissolving a polymer compound having a molecular structure containing a closed-ring polyimide that already has closed imide rings, a thermal crosslinking component, and a photosensitive agent as repeating units (groups) in the molecular chain, in a solvent having a boiling point of about 200° C. or less, such as propylene glycol monomethyl ether, which is used in photoresists. The closed-ring polyimide-based material has mechanical properties (elongation) similar to those of the polyimide material used for the passivation film 5. The back surface protective film 14, for example, has a heat-resistant temperature in a range of at least about 200 degrees C. but less than 400 degrees C. and thus, may withstand the annealing process performed when the passivation film 5 is formed.

In other words, in the process at step S8, the closed-ring polyimide-based material is applied to the back surface 1b of the semiconductor wafer 1 by a spin-coat method, and the solvent (organic solvent) in the closed-ring polyimide-based material is vaporized by an annealing process. The closed-ring polyimide-based material contains a closed-ring polyimide that has already been imidized in a solvent and thus, by simply vaporizing the solvent in the closed-ring polyimide-based material and performing sintering, the back surface protective film 14, which has mechanical properties similar to those of the passivation film 5, may be formed by a relatively low-temperature annealing process. The sintered body of the closed ring polyimide that remains attached to the back surface 1b of the semiconductor wafer 1 constitutes the back surface protective film 14. The back surface protective film 14 is formed in at least the center portion 1b-1 of the back surface 1b of the semiconductor wafer 1 so as to cover all the chip regions 10a of the semiconductor wafer 1.

The back surface protective film 14 protects the back device element structures 4 of the back surface 1b of the semiconductor wafer 1. The back surface protective film 14 has a function of suppressing the adhesion of foreign matter and the occurrence of defects (scratches, contamination) at the back surface 1b of the semiconductor wafer 1, during the process at later-described step S9. A thickness of the back surface protective film 14 is at least equivalent to a height of the foreign matter 15a, such as particles, present on the stage 15 (refer to FIG. 19) of the spin coater used at later-described step S9 and specifically, for example, is about 1 μm or more and preferably, may be at 2 μm or more. The back surface protective film 14 is soluble in organic solvents and thus, may be dissolved and removed by an organic solvent without applying stress to semiconductor wafer 1 or leaving any adhesive or other residue on back surface 1b of semiconductor wafer 1.

Next, as depicted in FIG. 9, the semiconductor wafer 1 is placed on the stage 15 of the spin coater with the back surface 1b facing downward (facing the stage 15) via the back surface protective film 14 and the polyimide 5a (portion with oblique line hatching) is applied to the front surface 1a of the semiconductor wafer 1 by a spin-coat method, thereby forming the passivation film 5 (step S9: front surface process). In the process at step S9, the passivation film 5 may be patterned by photolithography and etching. The passivation film 5 may be patterned to form openings exposing the scribe regions and electrode pads (the front electrodes 3). The scribe regions are portions between the chip regions 10a that are adjacent to each other and the scribe regions surround peripheries of the chip regions 10a in a plan view. The back surface 1b of the semiconductor wafer 1 is protected by the back surface protective film 14 and thus, is not in direct contact with the stage 15. Even in an instance when the foreign matter 15a is present on the stage 15, the foreign matter 15a does not reach the back surface 1b of the semiconductor wafer 1 due to the back surface protective film 14. Therefore, defects such as scratches and contamination due to the foreign matter 15a on the stage 15 do not occur at the back surface 1b of the semiconductor wafer 1.

Further, during the process at step S9, while the polyimide 5a, which is in a mist state, goes to the back surface 1b from the front surface 1a of the semiconductor wafer 1, the back surface 1b of the semiconductor wafer 1 is covered by the back surface protective film 14 and thus, the polyimide 5a does not adhere to the back surface 1b of the semiconductor wafer 1. The foreign matter 15a on the stage 15 and the polyimide 5a that is in a mist state floating in a periphery of the stage 15 adhere to the back surface protective film 14 and are removed together with the back surface protective film 14. The outer peripheral portion 1b-2 of the semiconductor wafer 1 is a non-operating region free of the chip regions 10a and thus, the polyimide 5a may adhere hereto. For example, a polyamic acid (polyamidic acid), which is a precursor of a polyamide, may be used as a material of the passivation film 5.

The process at step S9 includes precuring the passivation film 5 by an annealing process of about 200 degrees C. and a process of forming the passivation film 5 into a desired pattern by photolithography and etching with an alkaline solvent. For example, in an instance in which the back surface 1b of the semiconductor wafer 1 is protected by a resist film, when the annealing process is performed at a temperature equal to or higher than the heat resistant temperature (about 150 degrees C. to 200 degrees C.) of the resist film, it may become impossible to peel the resist film and thus, subsequent processes have to be performed at temperatures below the heat resistant temperature of the resist film. On the other hand, in the first embodiment, the back surface protective film 14 having a heat resistant temperature higher than the precuring temperature of the passivation film 5 is used and thus, the method of manufacturing the semiconductor device of the second reference example (refer to FIG. 19) may be applied with nearly no design changes.

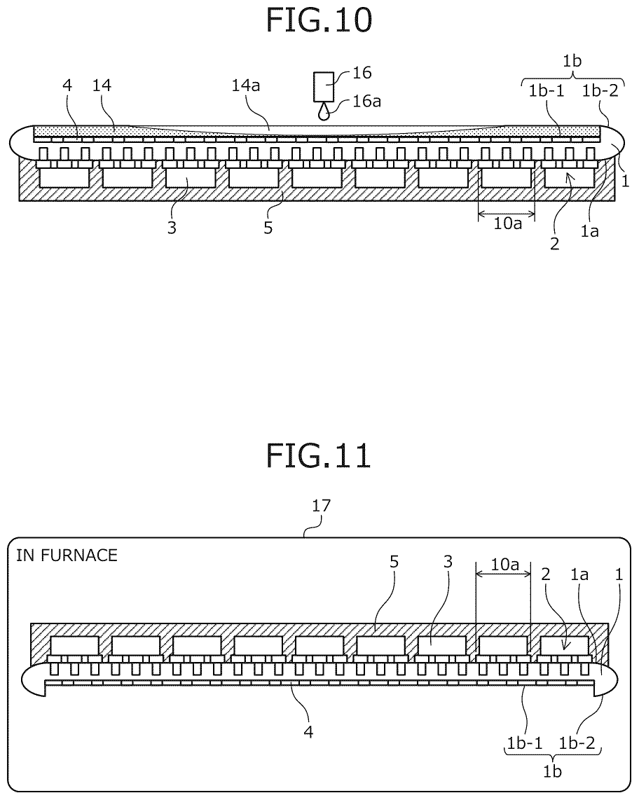

Next, as depicted in FIG. 10, using single-wafer spin peeling equipment, a chemical solution 16a is applied from a nozzle 16 positioned above the back surface 1b of the semiconductor wafer 1, thereby dissolving and removing the back surface protective film 14 (step S10: removal process). In particular, the outer peripheral portion 1b-2 of the semiconductor wafer 1 is clamped with the back surface 1b of the semiconductor wafer 1 facing upward. The semiconductor wafer 1 is maintained at a predetermined height position without being in contact with a stage or the like. Further, the chemical solution 16a is applied onto the back surface 1b of the semiconductor wafer 1 while the semiconductor wafer 1 is rotated around a shaft that passes through substantially the center of the semiconductor wafer 1 and is orthogonal to the back surface 1b of the semiconductor wafer 1. The back surface protective film 14 is dissolved by the chemical solution 16a and a dissolved portion 14a of the back surface protective film 14 is expelled off the semiconductor wafer 1 by centrifugal force.

The chemical solution 16 spreads along the back surface 1b of the semiconductor wafer 1 by centrifugal force and is expelled off the semiconductor wafer 1 from an outer periphery of the semiconductor wafer 1, at an angle substantially parallel to the back surface 1b of the semiconductor wafer 1. Similar to the chemical solution 16a, the dissolved portion 14a of the back surface protective film 14 dissolved by the chemical solution 16a is also expelled from the semiconductor wafer 1 by centrifugal force, at an angle substantially parallel to the back surface 1b of the semiconductor wafer 1. Thus, the passivation film 5 at the front surface 1a of the semiconductor wafer 1 is not adversely affected by the chemical solution 16a. For the chemical solution 16a, for example, an alkaline (basic) organic solvent may be used. In particular, for the chemical solution 16a, for example, an alkanolamine (alcoholamine, ethanolamine) organic solvent may be used.

Next, as depicted in FIG. 11, the semiconductor wafer 1 is placed in a furnace 17, the semiconductor wafer 1 being maintained so as to not come in contact with inner walls of the furnace 17, and an annealing process is performed at a high temperature, for example, 350 degrees C. or higher (preferably, 370 degrees C. or higher) thereby curing the passivation film 5 (the polyimide 5a is dehydrated, cyclized and thereby cured) (step S11). The passivation film 5 is cured and thus, it is possible to suppress cracking of the passivation film 5 when the semiconductor device is used in a harsh environment where the semiconductor device is subjected to a thermal load. Annealing by a furnace (the present treatment and the treatment at step S7 described above) is performed with the outer peripheral portion 1b-2 of the semiconductor wafer 1 being clamped or the like and thus, may be performed without the center portion 1b-1 (effective region where the chip regions 10a are disposed) of the back surface 1b of the semiconductor wafer 1 being in contact with a stage or jig.

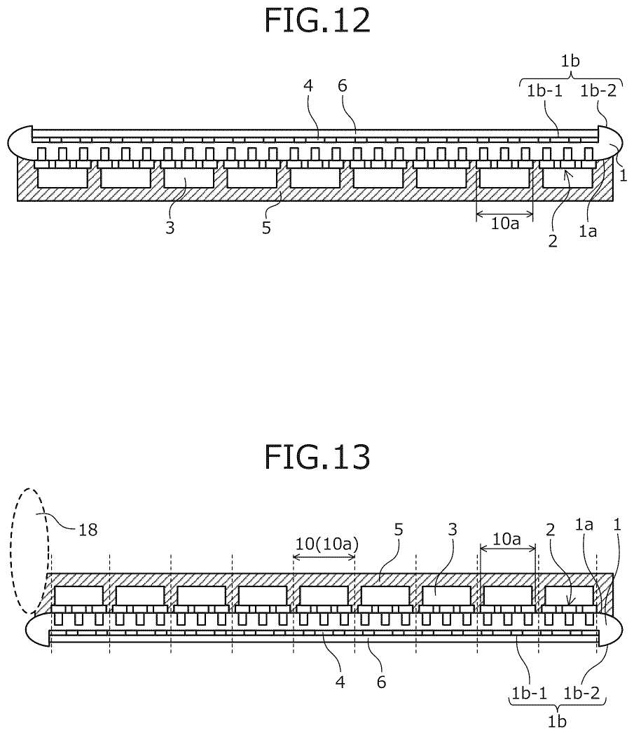

Next, as depicted in FIG. 12, a surface electrode (back electrode) 6 of the back surface 1b of the semiconductor wafer 1 is formed (step S12). Preferably, the back electrode 6 may be formed at a timing as close as possible to the end of the manufacturing process of the semiconductor device. A reason for this is as follows. When the back electrode 6 is formed at the back surface 1b of the semiconductor wafer 1 that has been made thinner by back surface grinding, the semiconductor wafer 1 tends to warp. When manufacturing processes are performed on the semiconductor wafer 1 that has warped and the semiconductor wafer 1 is transported, cracks may occur in the semiconductor wafer 1. Therefore, preferably, as far as possible, processes of the manufacturing process are performed before the back electrode 6 is formed.

Further, in an instance in which the back electrode 6 contains a heavy metal, when an annealing process is performed after the back electrode 6 is formed, the heavy metal contained in the back electrode 6 diffuses in the semiconductor wafer 1. Having diffused into the semiconductor chips 10 (the semiconductor wafer 1), the heavy metal becomes a factor that increases leakage current at pn junctions of the semiconductor device. The back electrode 6 is a stacked layer of films in which, for example, an Al alloy film or an Al film, titanium (Ti) film, a nickel (Ni) film, and a gold (Au) film or a silver (Ag) film are sequentially stacked in the order stated. A thickness of the back electrode 6 is, for example, about 2 μm or less and is thinner (less) than a height of the rib portion of the back surface 1b of the semiconductor wafer 1. The height of the rib portion of the back surface 1b of the semiconductor wafer 1 is a difference in the height of the center portion 1b-1 of the back surface 1b of the semiconductor wafer 1 and the height of the outer peripheral portion 1b-2 of the back surface 1b of the semiconductor wafer 1 and, for example, is not more than about 500 μm. Thereafter, as depicted in FIG. 13, the semiconductor wafer 1 is diced (cut) along the scribe regions by a dicing blade 18 thereby dicing the chip regions 10a of the semiconductor wafer 1 into the individual semiconductor chips 10 (step S13), whereby the semiconductor devices (the semiconductor chips 10) are completed.

The processes performed to the semiconductor wafer 1, at the front surface 1a thereof, include about 70 processes, and as compared to the processes (about 30 processes) performed to the back surface 1b of the semiconductor wafer 1, accounts for a large portion of total processes of the manufacturing process for the semiconductor device and thus, the stress load applied to the semiconductor wafer 1 is relatively large. Therefore, preferably, of all the processes performed to the semiconductor wafer 1 at the front surface 1a thereof, as many processes as possible may be performed before the thickness of the semiconductor wafer 1 is reduced (process as step S4), that is, while the thickness of the semiconductor wafer 1 is thick. Further, formation processes of the front device element structures 2 (processes at step S1) include an annealing process at a temperature of at least about 1200 degrees C. and thus, preferably, may be performed before the processes (maximum annealing temperature being about 800 degrees C.) that are to be performed to the back surface 1b of the semiconductor wafer 1.

Further, when the heat-resistant temperature of the back surface protective film 14 is higher than the temperature for curing the passivation film 5, the passivation film 5 may be cured with the back surface 1b of the semiconductor wafer 1 being protected by the back surface protective film 14. In this instance, the back surface protective film 14 suffices to be removed after the passivation film 5 is cured (process at step S11) but before the back electrode 6 is formed (process at step S12). Further, in an instance in which the semiconductor device is to be used under an environment free of thermal load, diffusion of metal atoms contained in the front electrodes 3 and cracking of the passivation film 5 do not easily occur and thus, sintering of the front electrodes 3 and/or curing of the passivation film 5 may be omitted.

The method of manufacturing the semiconductor device according to the first embodiment, for example, may be implemented by executing a prepared program on a computer such as a personal computer, a workstation, a database server, a web server, or the like. Further, the program for implementing the method of manufacturing the semiconductor device according to the first embodiment is recorded on a computer-readable recording medium such as a solid-state drive (SSD), a hard disk, a Blu-ray (BD) Disc (trademark), etc., is readout from the recording medium by a computer, server, etc. and executed. Further, the program may be a transmission medium that may be distributed via a network such as the Internet.

An example of the structure of the semiconductor device (the semiconductor chips 10) fabricated by the method of manufacturing the semiconductor device according to the first embodiment is described taking a RC-IGBT as an example. FIG. 14 is a cross-sectional view of an example of the structure of the semiconductor device fabricated by the method of manufacturing the semiconductor device according to the first embodiment. A semiconductor device 20 according to the first embodiment depicted in FIG. 14 is a RC-IGBT in which in in an active region of the semiconductor chip 10, an IGBT region 21 constituting an operating region of an IGBT and a FWD region 22 constituting an operating region of a freewheeling diode (FWD) are provided adjacent to each other. In an instance in which the semiconductor device 20 is applied to an IGBT, the FWD region 22 is omitted.

The active region is a region through which a main current flows when the device element is on; the active region is disposed in substantially a center of the semiconductor chips 10. Between the active region and an end of the semiconductor chip 10 is an edge termination region. The edge termination region surrounds a periphery of the active region in a plan view and has a function of relaxing electric field of a front side of the semiconductor chip 10 and sustaining a breakdown voltage. In the edge termination region, a voltage withstanding structure such as a guard ring, a field limiting ring (FLR), a junction termination extension (JTE) structure, etc. is disposed. The breakdown voltage is a voltage of an upper limit, at which no destruction or malfunction of the device element occurs at an operating voltage.

In the IGBT region 21, multiple unit cells (functional units of a device element) of an IGBT are disposed adjacent to one another. In the FWD region 22, multiple unit cells of a FWD are disposed adjacent to one another. The IGBT of the IGBT region 21 and the FWD of the FWD region 22 are connected to each other in antiparallel. The IGBT region 21 and the FWD region 22, for example, are disposed adjacently and repeatedly alternate with one another in a direction parallel to the front surface of the semiconductor chip 10. The front surface and the back surface of the semiconductor chip 10 correspond, respectively, to the front surface 1a and the back surface 1b of the semiconductor wafer 1 described above (refer to FIG. 13). In the semiconductor chip 10, an n⁻-type drift region 31 is provided.

A portion of each of the semiconductor chips 10 excluding the front device element structures 2 and the back device element structures 4 constitutes the n⁻-type drift region 31. The n⁻-type drift region 31 reaches an end of the semiconductor chip 10 from the active region. The front device element structures 2 are configured by a p-type base region 32, n⁺-type emitter regions 33, p⁺⁺-type contact regions 34, trenches 36, gate insulating films 37, and gate electrodes 38. The back device element structures 4 are configured by an n-type FS layer 41, a p⁺-type collector region 42, and an n⁺-type cathode region 43. The front device element structures 2 and the back device element structures 4 are formed by the processes at steps S1 and S5 of the method of manufacturing the semiconductor device according to the first embodiment.

The p-type base region 32 is in contact with the n⁻-type drift region 31, between the front surface of the semiconductor chip 10 and the n⁻-type drift region 31. The p-type base region 32 is provided in an entire area of the active region, from the IGBT region 21 to the FWD region 22. In the FWD region 22, the p-type base region 32 functions as a p-type anode region of the FWD. In the IGBT region 21, the n⁺-type emitter regions 33 and the p⁺⁺-type contact regions 34 are selectively provided between the front surface of the semiconductor chip 10 and the p-type base region 32 and are in contact with the p-type base region 32.

The p₊₊-type contact regions 34 may be omitted. In this instance, instead of the p₊₊-type contact regions 34, the p-type base region 32 reaches the front surface of the semiconductor chip 10. In the IGBT region 21, between the trenches 36 that are adjacent to each other, an n-type accumulation layer 35 may be provided between and in contact with the n⁻-type drift region 31 and the p-type base region 32. The n-type accumulation layer 35 is a minority carrier barrier of the n⁻-type drift region 31 when the IGBT turns on, and functions as a carrier storage (CS) layer that stores minority carriers in the n⁻-type drift region 31.

In an entire area of the active region, the trenches 36 extend linearly in a same direction parallel to the front surface of the semiconductor chip 10, forming a striped pattern. In the IGBT region 21, the trenches 36 penetrate through the n⁺-type emitter regions 33, the p-type base region 32, and the n-type accumulation layer 35 in a depth direction from the front surface of the semiconductor chip 10 and terminate in the n⁻-type drift region 31. In the FWD region 22, the trenches 36 penetrate through the p-type base region 32 in the depth direction from the front surface of the semiconductor chip 10 and terminate in the n⁻-type drift region 31. In the trenches 36, the gate electrodes 38 are provided via the gate insulating films 37.

The p-type base region 32, the n⁺-type emitter regions 33, and the n-type accumulation layer 35 are in contact with the gate insulating films 37 at sidewalls of the trenches 36. In the IGBT region 21, each unit cell of the IGBT is configured by a portion between a center of one of the trenches 36 and a center of an adjacent one of the trenches 36. In the FWD region 22, each unit cell of the FWD is configured by a portion between a center of one of the trenches 36 and a center of an adjacent one of the trenches 36. An interlayer insulating film 39 is provided in substantially an entire area of the front surface of the semiconductor chip 10 and covers the gate electrodes 38. The interlayer insulating film 39, for example, contains boron phosphorus silicon glass (BPSG) or a phosphorus silicon glass (PSG).

An emitter electrode 40 is provided on the interlayer insulating film 39 in substantially an entire area of the active region and is embedded in contact holes 39a, 39b of the interlayer insulating film 39. The emitter electrode 40 constitutes the front electrode 3 formed at the process at step S2 of the method of manufacturing the semiconductor device according to the first embodiment. The emitter electrode 40 is in ohmic contact with the front surface of the semiconductor chip 10 via the contact holes 39a, 39b. In the IGBT region 21, the emitter electrode 40 is electrically connected to the p-type base region 32, the n⁺-type emitter regions 33, and the p⁺⁺-type contact regions 34 via the contact holes 39a.

In the FWD region 22, the emitter electrode 40 is electrically connected to the p-type base region 32 via the contact holes 39b and further serves as an anode electrode. While not depicted in FIG. 14, the front surface of the semiconductor chip 10 is covered by the passivation film 5 (refer to FIG. 13). The emitter electrode 40, which is exposed in openings (not depicted) of the passivation film 5, functions as an emitter pad (electrode pad). The n-type FS layer 41, the p⁺-type collector region 42, and the n⁺-type cathode region 43 are each provided between the back surface of the semiconductor chip 10 and the n⁻-type drift region 31.

The n-type FS layer 41, the p⁺-type collector region 42, and the n⁺-type cathode region 43 are diffused regions formed by ion implantation from the back surface of the semiconductor chip 10. The n-type FS layer 41 is provided in an entire area of the active region, at a depth position apart from the back surface of the semiconductor chip 10. The n-type FS layer 41 may be omitted. In the IGBT region 21, the p⁺-type collector region 42 is provided in an entire area between the back surface of the semiconductor chip 10 and the n-type FS layer 41. In the FWD region 22, the n⁺-type cathode region 43 is provided in an entire area between the back surface of the semiconductor chip 10 and the n-type FS layer 41.

The p⁺-type collector region 42 and the n⁺-type cathode region 43 are adjacent to each other in a direction parallel to the back surface of the semiconductor chip 10. A collector electrode 44 is provided in an entire area of the back surface of the semiconductor chip 10. The collector electrode 44 constitutes the back electrode 6 formed by the process at step S12 of the method of manufacturing the semiconductor device according to the first embodiment. The collector electrode 44 is in contact with and electrically connected to the p⁺-type collector region 42 at the back surface of the semiconductor chip 10. The collector electrode 44 is in contact with and electrically connected to the n⁺-type cathode region 43 at the back surface of the semiconductor chip 10 and further serves as a cathode electrode.

As described, according to the first embodiment, the back device element structures are formed and an annealing process by the furnace is performed, thereafter the back surface (non-treated surface) of the semiconductor wafer is protected by the back surface protective film and subsequently, predetermined processes are performed to the semiconductor wafer, at the front surface (treated surface) thereof. In the predetermined processes performed to the semiconductor wafer at the front surface thereof, among the structure components of the semiconductor wafer, at the front surface thereof, structure components having a heat-resistant temperature lower than the temperature of the annealing process by the furnace are formed after the annealing process by the furnace. At this time, the back surface of the semiconductor wafer is protected by the back surface protective film and thus, an occurrence of defects (scratches, contamination), which cause leakage defects at the back surface of the semiconductor wafer, may be suppressed.

Further, when the predetermined processes are performed to the semiconductor wafer at the front surface thereof, the back surface of the semiconductor wafer is protected by the back surface protective film and thus, adhesion of foreign matter to the back surface of the semiconductor wafer may be suppressed; the adhesion of foreign matter is a factor of thermal destruction during device operation. For example, the back surface protective film contains the closed-ring polyimide-based material and the heat-resistant temperature thereof is relatively high. Therefore, the passivation film may be formed at the front surface of the semiconductor wafer with the back surface of the semiconductor wafer being protected by the back surface protective film. When the polyimide is applied to the front surface of the semiconductor wafer by a spin-coat method, adhesion of the polyimide, which is in a mist state, to the back surface of the semiconductor wafer may be suppressed.

Foreign matter present on the stage of the semiconductor manufacturing equipment and material splattered on the back side of the semiconductor wafer when the predetermined processes are performed to the front side of the semiconductor wafer adhere to the back surface protective film and thus, may be removed together with the back surface protective film. Further, according to the first embodiment, as compared to the method of manufacturing the semiconductor device of the second reference example (refer to FIG. 19), while the formation process and the removal process for the back surface protective film are added, as described, adhesion of foreign matter, occurrence of defects, etc. at the back surface of the semiconductor wafer are suppressed and thus, the occurrence rate of defective chips is reduced and the product yield is improved. Therefore, it is surmised that the product cost may be kept relatively unchanged as compared to the product cost in the case of the method of manufacturing the semiconductor device of the second reference example.

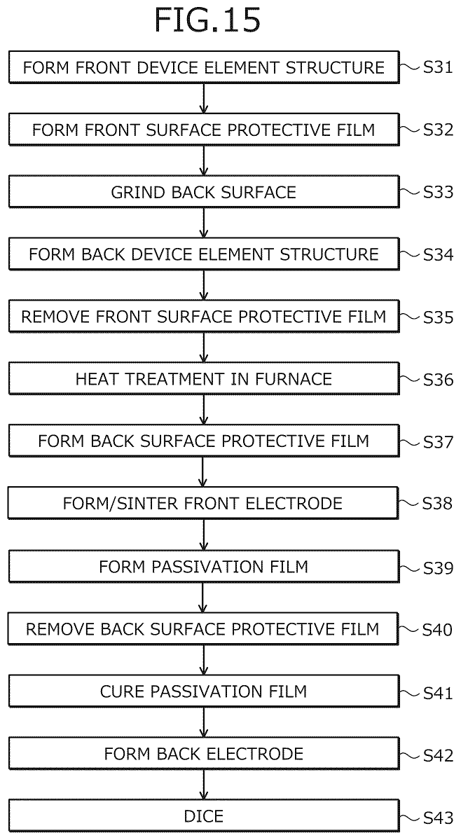

A method of manufacturing a semiconductor device according to a second embodiment solving the problems above is described. FIG. 15 is a flowchart showing an outline of the method of manufacturing the semiconductor device according to the second embodiment solving the problems above is described. In the method of manufacturing the semiconductor device according to the second embodiment, the timing when the front electrodes 3 are formed differs from the timing in the method of manufacturing the semiconductor device according to the first embodiment (refer to FIG. 1) and is useful in instances in which the temperature of the annealing process by the furnace exceeds the heat resistant temperature (about 500 degrees C.) of aluminum (Al), which is a material of the front electrodes 3.

In particular, in the second embodiment, first, similar to the process at step S1 of the first embodiment, the semiconductor wafer 1 is prepared and the front device element structures 2 are formed (step S31). Next, similar to the first embodiment, the formation of the front surface protective film 11 (step S32), the back surface grinding (step S33), the formation of the back device element structures 4 (step S34), the removal of the front surface protective film 11 (step S35), the annealing process by the furnace (step S36), and the formation of the back surface protective film 14 (step S37) are sequentially performed.

Next, similar to the process at step S2 of the first embodiment, the front electrodes 3 are formed and sintered (step S38: front surface process). In the process at step S38, the semiconductor wafer 1 is placed, for example, on a stage of sputtering equipment via the back surface protective film 14 with the back surface 1b facing downward (facing the stage). During the process at step S38, the back surface 1b of the semiconductor wafer 1 is not in direct contact with the stage and thus, adhesion of foreign matter to the back surface 1b of the semiconductor wafer 1 and/or the occurrence of defects due to foreign matter on the stage of the sputtering equipment may be suppressed.

Grain growth progresses the higher is the deposition temperature of the front electrodes 3 and the crystallinity of the front electrodes 3 improves. Preferably, the deposition temperature of the front electrodes 3 may be about 250 degrees C. or higher. Further, the formation of the front electrodes 3 includes patterning of the front electrodes 3 by photolithography and etching and using a resist film as an etching mask during patterning. The heat-resistant temperature of the back surface protective film 14 is at least equal to a sintering temperature of the resist and thus, the front electrodes 3 may be patterned while the back surface 1b of the semiconductor wafer 1 is protected by the back surface protective film 14.

Sintering the front surface electrode 3 promotes the migration (recrystallization) of metal atoms in the front surface electrode 3 and thereby may reduce the additional stress that the metal atoms such as Al in the front surface electrode 3 apply to the passivation film 5 during operation of the semiconductor device. The temperature at which the front electrodes 3 are sintered may be at least equal to the curing temperature of the passivation film 5 and, for example, is 380 degrees C. or higher. Sintering the front electrodes 3 may suppress cracking of the passivation film 5 when the semiconductor device is used under harsh environments with thermal loads, by migrating (recrystallizing) the metal atoms from the front electrodes 3 and relaxing stress.

Subsequently, similar to the first embodiment, the formation of the passivation film 5 (step S39), the removal of the back surface protective film 14 (step S40), the curing of the passivation film 5 (step S41), the formation of the back electrode 6 (step S42), and the dicing of the semiconductor wafer 1 (step S43) are sequentially performed, whereby the semiconductor devices are completed. At the processes at steps S38 and S39, the same back surface protective film 14 may be used. The semiconductor device manufactured by the method of manufacturing the semiconductor device according to the second embodiment is the same as the semiconductor device depicted in FIG. 14.

At steps S32 to S37, the processes performed to the semiconductor wafer 1 in a state of the semiconductor wafer 1 being free of the front electrodes 3 are the same as the processes at steps S3 to S8 of the first embodiment, respectively. The annealing process by the furnace at step S36 may be performed at a temperature that exceeds the heat-resistant temperature of the front electrodes 3. The processes at steps S39 to S43 are the same as the processes at steps S9 to S13 of the first embodiment, respectively. The states during the processes at steps S39 to S43 are the same as the states depicted in FIGS. 9 to 13.

As described, according to the second embodiment, even in an instance in which the front electrodes are formed after the annealing process by the furnace, the back surface of the semiconductor wafer is protected by the back surface protective film when the front electrode is formed and effects similar to those of the first embodiment may be obtained.

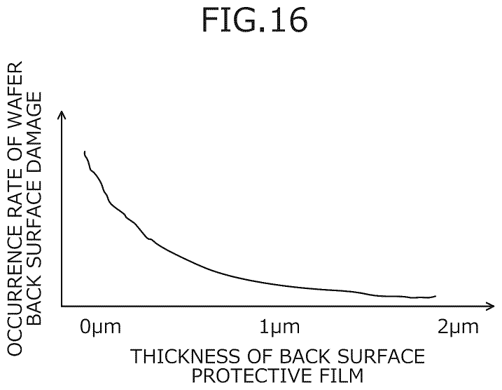

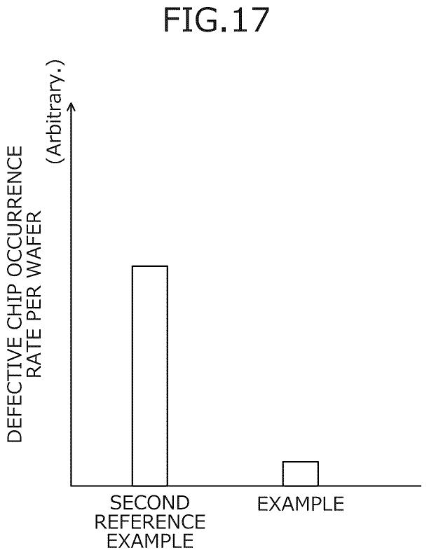

FIG. 16 is a characteristics diagram schematically depicting a relationship between a scratch occurrence rate of the back surface of the semiconductor wafer and thickness of the back surface protective film. FIG. 17 is a characteristics diagram schematically depicting a defective chip occurrence rate per semiconductor wafer. In FIGS. 16 and 17, “example” is data estimated based on the inventor's experience. In FIG. 17, the second reference example is experimental data obtained by the inventor. It was confirmed by the inventor that in an instance in which the back surface 1b of the semiconductor wafer 1 is protected by a resist film and the thickness of the resist film is set to be about 2 μm, when the semiconductor wafer 1 is placed on a general stage of semiconductor manufacturing equipment with the back surface 1b facing downward (facing the stage) via the resist film, the back surface 1b of the semiconductor wafer 1 may be protected from foreign matter on the stage.

Further, it was confirmed by the inventor that in an instance in which the depth of the back device element structures 4 of the IGBT are relatively shallow from the back surface 1b of the semiconductor wafer 1 (for example, about 2 μm or less) and the thickness of the back electrode 6 is increased to about 2 μm, during electrical testing, even when the semiconductor wafer 1 or the semiconductor chips 10 are placed with the back electrode 6 facing downward and the back electrode 6 is in contact with the stage, defective chip do not occur. Based on these findings, provided that the thickness of the back surface protective film 14 is about 2 μm, protection of the back surface 1b of the semiconductor wafer 1 from foreign matter on the stage is sufficient and it is surmised that when the thickness of the back surface protective film 14 is about 1 μm, scratches caused by foreign matter on the stage tend to be less likely to occur on the back surface 1b of the semiconductor wafer 1 (FIG. 16).

Based on this, it may be said that the rate of defective chips per semiconductor wafer 1 in the semiconductor device manufacturing method of the first embodiment (refer to FIG. 1) is obtained by subtracting the number of defective chips caused by the adhesion of foreign matter and the occurrence of defects on the exposed back surface 101b of the semiconductor wafer 101 during the formation of the passivation film 105 in the semiconductor device manufacturing method of the second reference example (refer to FIGS. 19 and 24). Based on the inventor's experience, it is estimated that the rate of defective chips occurring per semiconductor wafer 1 in the semiconductor device manufacturing method of the first embodiment (indicated as an example in FIG. 17) may be reduced to about 1/10 of the rate of defective chips occurring per semiconductor wafer 101 in the semiconductor device manufacturing method of the second reference example (refer to FIG. 17).

As for the method of manufacturing the semiconductor device according to the second embodiment (refer to FIG. 15), similar to the method of manufacturing the semiconductor device according to the first embodiment, when the passivation film 5 is formed, the back surface 1b of the semiconductor wafer 1 is protected by the back surface protective film 14 and therefore, it is surmised that effects similar to those of the method of manufacturing the semiconductor device according to the first embodiment are obtained.

In the foregoing, the present disclosure is not limited to the embodiments above and various modifications within a range not departing from the spirit of the disclosure are possible. For example, the present disclosure is not limited to an IGBT or a RC-IGBT and is applicable to a vertical semiconductor device having a surface electrode on each main surface of the semiconductor chip and to a semiconductor device having, as a back device element structure, diffused regions that need dopant activation by an annealing process by the furnace. Thus, the present disclosure is applicable to, for example, metal oxide semiconductor field effect transistors (MOSFETs) having insulated gates with a three-layer metal-oxide-semiconductor structure, freewheeling diodes (FWDs), and the like.

In an instance in which the present disclosure is applied to a MOSFET, in the structure of the semiconductor device according to the first embodiment depicted in FIG. 14, the FWD region is omitted and instead of p⁺-type collector regions, an n⁺-type drain region is provided, whereby all regions of the active region may be MOS regions. In this instance, the n⁺-type emitter regions, the emitter electrode, and the collector electrode of FIG. 14 are replaced with n⁺-type source regions, a source electrode, and a drain electrode, respectively. In an instance in which the present disclosure is applied to an FWD, the IGBT region is omitted. In this instance, the trenches, the gate insulating films, and the gate electrodes may also be omitted. Further, the present disclosure is not limited to processes performed to the front side of a semiconductor wafer and various processes involving an annealing process of 200 degrees C. or higher performed to a semiconductor wafer may be performed with the back surface of the semiconductor wafer being protected by the back surface protective film. Further, in the embodiments, while a first conductivity type is assumed to be an n-type and a second conductivity type is assumed to be a p-type, the present disclosure is similarly implemented when the first conductivity type is a p-type and the second conductivity type is an n-type.

The method of manufacturing the semiconductor device according to the present disclosure achieves an effect in that yield may be enhanced.

As described, the method of manufacturing the semiconductor device according to the present disclosure is useful for vertical semiconductor devices used in power converting equipment, power source devices of various types of industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A method of manufacturing a semiconductor device having
a semiconductor substrate having a front surface and a back surface,
a front device element structure formed at the front surface of the semiconductor substrate, and
a back device element structure formed at the back surface of the semiconductor substrate,
the method comprising:
providing a semiconductor wafer having a first main surface and a second main surface;
as a back surface process, forming the back device element structure in the semiconductor wafer at the second main surface;
as a thermal process, heating the semiconductor wafer in a furnace after performing the back surface process;
as a back surface protection process, protecting the second main surface of the semiconductor wafer using a back surface protective film after performing the thermal process;
as a front surface process, performing a process to at least the first main surface of the semiconductor wafer while the second main surface of the semiconductor wafer is being protected by the back surface protective film, said process including a heat treatment of 200 degrees C. or higher; and
as a removal process, removing the back surface protective film after performing the front surface process, wherein
the back surface protection process further includes forming the back surface protective film using a non-photosensitive resin material, the back surface protective film being heat resistant to a temperature of 200 degrees C. or higher.

2. The method according to claim 1, wherein the non-photosensitive resin material is soluble in an organic solvent.

3. The method according to claim 1, wherein the non-photosensitive resin material is a closed-ring polyimide-based material.

4. The method according to claim 1, wherein the back surface protective film is formed to have a thickness of 1 μm or more.

5. The method according to claim 1, wherein
the front surface process further includes performing a spin-coat method to apply a polyimide to the first main surface of the semiconductor wafer, to thereby form a passivation film, and
the passivation film is cured by the heat treatment in the front surface process.

6. The method according to claim 1, further comprising forming the front device element structure in the semiconductor wafer at the first main surface thereof, before performing the back surface process, wherein
the front surface process further includes forming a front electrode at the first main surface of the semiconductor wafer, and electrically connecting the front electrode to the front device element structure, the front electrode being sintered by the heat treatment in the front surface process.

7. The method according to claim 1, wherein
the back surface process further includes ion-implanting a dopant from the second main surface of the semiconductor wafer to thereby form a diffused region of the back device element structure, the diffused region having a predetermined conductivity type, and
the thermal process further includes activating the dopant.

8. The method according to claim 1, wherein the removal process further includes dissolving the back surface protective film in an organic solvent to thereby remove the back surface protective film.

9. The method according to claim 1, further comprising forming a back electrode at the second main surface of the semiconductor wafer after performing the removal process, and electrically connecting the back electrode to the back device element structure.
